(19) United States
(12) Patent Application Publication
(10) Pub. No.: US 2013/0015537 A1
(43) Pub. Date: Jan. 17, 2013

(54) PIEZORESISTIVE PRESSURE SENSOR AND PROCESS FOR PRODUCING A PIEZORESISTIVE PRESSURE SENSOR

(71) Applicants: Birgit Nowak, Teltow (DE); Bernhard Ostrick, Teltow (DE); Andreas Peschka, Michendorf (DE)

(72) Inventors: Birgit Nowak, Teltow (DE); Bernhard Ostrick, Teltow (DE); Andreas Peschka, Michendorf (DE)

(73) Assignee: EPCOS AG, Munich (DE)

(21) Appl. No.: 13/514,260

(22) PCT Filed: Dec. 14, 2010
(86) PCT No.: PCT/EP2010/069645

§ 371 Date: Sep. 13, 2012

(30) Foreign Application Priority Data
Dec. 23, 2009 (DE) 10 2009 060 318.2

(51) Int. Cl. H01L 29/84; H01L 21/02

(52) U.S. Cl. 257/415; 438/50; 257/E29.324; 257/E21.002

(57) ABSTRACT

A pressure sensor (1) is provided which has a piezoresistive membrane (2) which can be deformed by the action of the pressure of a medium. The membrane (2) is arranged on a carrier substrate (3) and extends over an opening (32) in the carrier substrate (3). The pressure sensor (1) has a protective layer (4) to protect the membrane (2) from direct contact with a medium. The protective layer (4) covers the membrane (2) both in a first region (28) inside the opening (32) and in a second region (29) outside the opening (32). Furthermore, a process for producing a pressure sensor (1) is provided in which the protective layer (4) forms an etch stop for an etching process.

A pressure sensor in the form of a chip is provided which is preferably produced using MEMS technology. The abbreviation MEMS here stands for Micro-Electro-Mechanical System and is a manufacturing process in which, for example, small mechanical structures are inserted into the volume of a wafer. A pressure sensor of this type is sensitive to small changes in pressure and can be connected to data analysis systems in a space-saving and cost-effective manner by virtue of its integration into a wafer.

A pressure sensor is described in the document DE 43 15 962 C2 in which a measuring membrane of the pressure sensor is protected from a liquid or gaseous corrosive pressure medium by a protective housing.

An object of the invention is to provide a pressure sensor which is protected from a pressure medium in a particularly cost-effective and reliable manner.

A pressure sensor is provided which has a piezoresistive membrane which can be deformed by the action of the pressure of a medium. The membrane is arranged on a carrier substrate. The carrier substrate has an opening, wherein the membrane extends at least part of the opening. The pressure sensor also has a protective layer to protect the membrane from direct contact with the medium. The protective layer covers the membrane both in a first region that is situated inside the opening and in a second region that is situated outside the opening.

A region of the membrane is preferably considered to lie or to be situated inside the opening when this region is situated inside an orthogonal area of the cross sectional area of the opening, projected onto the membrane. In this case, that cross sectional area of the opening of the carrier substrate is considered which is situated on that side of the carrier substrate which faces the membrane. A region of the membrane lies or is situated outside the opening when the region lies outside this projected area. The region inside the opening is preferably a deformable part of the membrane and the region outside the opening is preferably a part of the membrane which rests on the carrier substrate.

The carrier substrate is preferably produced using MEMS technology. The carrier substrate can be, for example, formed from a silicon wafer in which the opening is introduced in an etching process. In the etching process, a thin layer of silicon can remain above the opening so that this layer can be used as a membrane for measuring a pressure. In an alternative manner of production, the etching process can be carried out in such a way that the opening passes completely through the carrier substrate and thus forms a through-hole in the carrier substrate. The membrane can then be applied in a subsequent step above the opening.

The membrane has piezoresistive resistors which change their electrical resistance in the event of mechanical stresses which occur, for example, when a pressure is acting on the membrane. The pressure of a medium can be determined by detecting and measuring the change in resistance. The pressure sensor can thus be designed as a relative pressure sensor or as an absolute pressure sensor. Electrical contacts are, for example, arranged on a region of the membrane that rests on the carrier substrate in order to detect the resistances. The contacts are in electrical contact with piezoresistive resistors and can be electrically connected to strip conductors of a printed circuit board by means of bonding wires.

The carrier substrate preferably has a top side and an underside. The protective layer is, for example, situated on the top side of the carrier substrate and is fixedly connected thereto. The membrane is, for example, arranged on that side of the protective layer facing away from the carrier substrate and is preferably fixedly connected to the protective layer. In this case the pressure sensor is preferably designed in such a way that the membrane is accessible from the underside of the carrier substrate for the action of the pressure of the medium.

The protective layer preferably completely covers the membrane inside the opening.

In this case, the protective layer inside the opening can prevent any direct contact of the medium with the membrane and thus forms reliable protection of the membrane.

The second region outside the opening preferably adjoins the first region inside the opening.

In this case, the protective layer extends from the first region inside the opening directly into a second region outside the opening. The medium on the inner edges of the opening can thereby be prevented from coming into direct contact with the membrane. The protective layer preferably completely covers the membrane inside the opening and extends in all directions along the surface of the membrane into regions outside the opening. In a preferred embodiment, the protective layer completely covers the membrane outside the opening.

The material of the carrier substrate can preferably be etched selectively against the material of the protective layer.

In this case, the protective layer can function as an etch stop in an etching process by means of which the opening is formed in the carrier substrate.

The protective layer preferably comprises at least one of the materials silicon dioxide and silicon nitride. Alternatively or additionally, the protective layer can also comprise other oxides such as, for example, SiₓO_{y}. The substrate is, for example, formed from a silicon wafer. In a chemical etching process, for example using an aqueous-alkali etchant, the silicon can selectively be etched against the mentioned materials of the protective layer.

In a further embodiment, the protective layer has, in the first region inside the opening, a different thickness than in the second region outside the opening. The thickness of the protective layer in the first region is preferably smaller than the thickness of the protective layer in the second region.

The differing thickness inside and outside the opening is, for example, created in the etching process in which the opening is formed. A partial layer of the protective layer can thereby be removed inside the opening. In this way, the thickness of the protective layer can specifically be configured in such a way that desired deformation properties of the membrane are configured.

In a further embodiment, the protective layer has an indentation facing the opening. The indentation can be preferably formed as a concave recess in the protective layer. The indentation has a depth which decreases in a direction from a center of the indentation, the center of the indentation preferably corresponding to a center of the opening, toward an inner wall of the opening or, in other words, toward a border of the indentation so that the thickness of the protective layer increases in a direction from the center of the indentation toward the inner wall of the opening and toward the border of the indentation. The position of the inner wall of the opening preferably corresponds to the border between the first and the second partial regions. Furthermore, the indentation can preferably completely be situated in the first region and can extend into the second region so that the indentation covers the first region and part of the partial region and the border of the indentation lies in the second region. In other words, the opening and the indentation of the protective layer form an undercut wherein the surface area of the indentation in a plane of the interface between the protective layer and the carrier substrate is larger than the surface area of the opening.

In a preferred embodiment, the indentation has a round, concave profile so that, advantageously, the flexural stress in the membrane, which occurs due to the pressure of a medium deforming the membrane, can be equally distributed.

In a further embodiment, the pressure sensor has at least one further layer which is arranged on a side of the membrane facing away from the protective layer. The further layer can also fulfill the function of a protective layer so that the membrane is protected on both sides from direct contact with the medium. The layer is, for example, deposited on the membrane by evaporation deposition.

In a further embodiment, the pressure sensor has a housing that is arranged on a side of the membrane facing away from the carrier substrate. The housing preferably can have a hollow space that adjoins the membrane.

The hollow space preferably adjoins the deformable region of the membrane that is situated above the opening. A vacuum which is enclosed by the membrane and the housing is, for example, formed in the hollow space. In this way, the absolute pressure of the medium can be measured.

According to a further embodiment, a process for producing a pressure sensor is provided, wherein a carrier substrate is provided on which a first layer is arranged to form a protective layer for protecting the membrane from direct contact with a medium. A second layer is arranged on the first layer to form a membrane. An opening is then formed in the carrier substrate so that at least a part of the layer thickness of the first layer remains above the opening.

A silicon-on-insulator (SOI) wafer can be, for example, used to produce the pressure sensor. A wafer of this type comprises a layer-forming silicon substrate on which an insulating layer, for example an oxide layer, is arranged. A further thin silicon layer is situated above the insulating layer. The protective layer can be formed from the insulating layer of the SOI wafer. The membrane can be formed from the further thin silicon layer.

The opening in the carrier substrate is preferably formed in a structuring etching process. The protective layer can thus act as an etch stop.

The opening is, for example, etched into the underside of the carrier substrate. In the case that the material of the carrier substrate can be etched selectively against the material of the protective layer, an opening is formed during the etching process which extends as far as the protective layer. The protective layer slows down the etching process or stops it altogether, so that at least a partial layer of the insulating layer is retained inside the opening after the etching process. In this way, it can be ensured in a cost-effective and easily controllable etching process that in the etching process a protective layer remains and covers the membrane above the opening in the carrier substrate.

According to a further embodiment, a further process for producing a pressure sensor is provided, wherein a carrier substrate is provided and an opening passing through the carrier substrate is formed in the carrier substrate. A functional substrate is additionally provided which on an outer side has a first layer for forming a protective layer to protect a membrane from direct contact with a medium, and arranged thereunder a second layer for forming a membrane. The functional substrate is applied with the first layer to the carrier substrate so that at least a part of the first layer is arranged above the opening in the carrier substrate. The first layer preferably covers and confines the opening from above. A part of the second layer of the functional substrate is thereby removed and a membrane is thus formed from the second layer.

In a further embodiment of a process for producing a pressure sensor, an indentation is formed in the protective layer, wherein the indentation faces the opening and is formed as a concave recess in the protective layer. The indentation is formed so as to have a depth which decreases in a direction from a center of the indentation, the center of the indentation preferably corresponding to a center of the opening, toward an inner wall of the opening or, in other words, toward a border of the indentation so that the thickness of the protective layer increases in a direction from the center of the indentation toward the inner wall of the opening and toward the border of the indentation.

In a further preferred embodiment, the indentation can be formed in the first region and can partially extend into the second region so that the opening and the indentation of the protective layer form an undercut. In a preferred embodiment, the indentation is formed with a round, concave profile so that, advantageously, the flexural stress in the membrane, which occurs due to the pressure of a medium deforming the membrane, can be equally distributed. The indentation can be formed for example by selectively etching the protective layer through the opening in combination with any of the before-mentioned process steps and embodiments.

This production process has the advantage that the opening in the carrier substrate can be introduced from the top side of the carrier substrate, in other words on the side on which the membrane is subsequently arranged. A chip area can be obtained in this way.

The pressure sensor provided and its advantageous embodiments are explained below with reference to schematic not-to-scale drawings, in which:

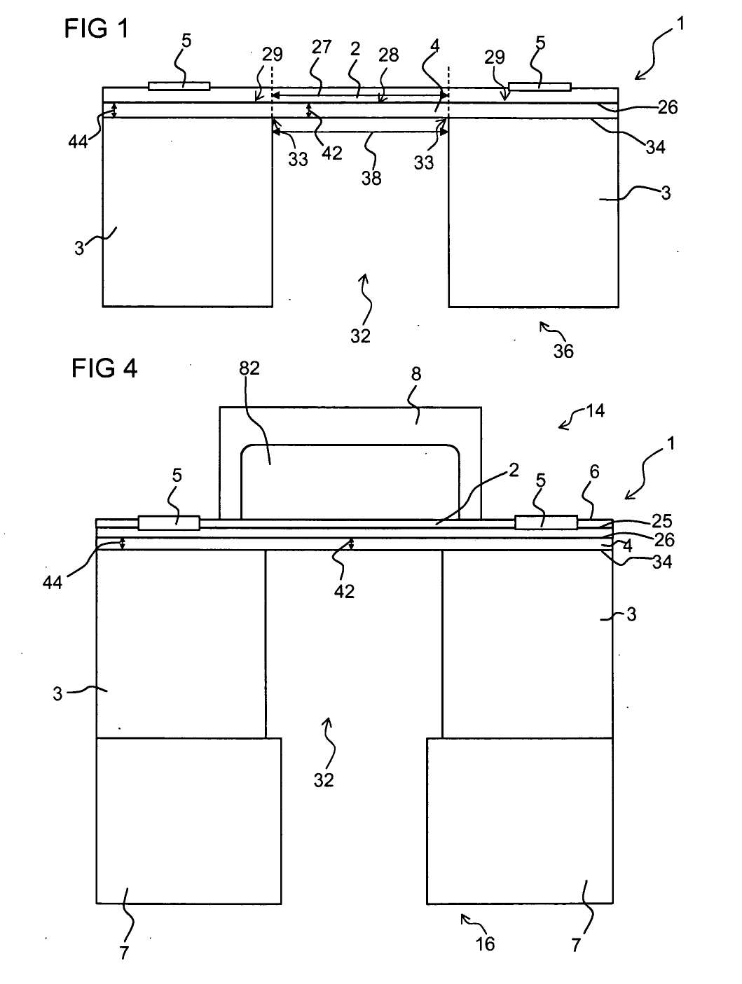

FIG. 1 shows a cross section of an embodiment of a pressure sensor,

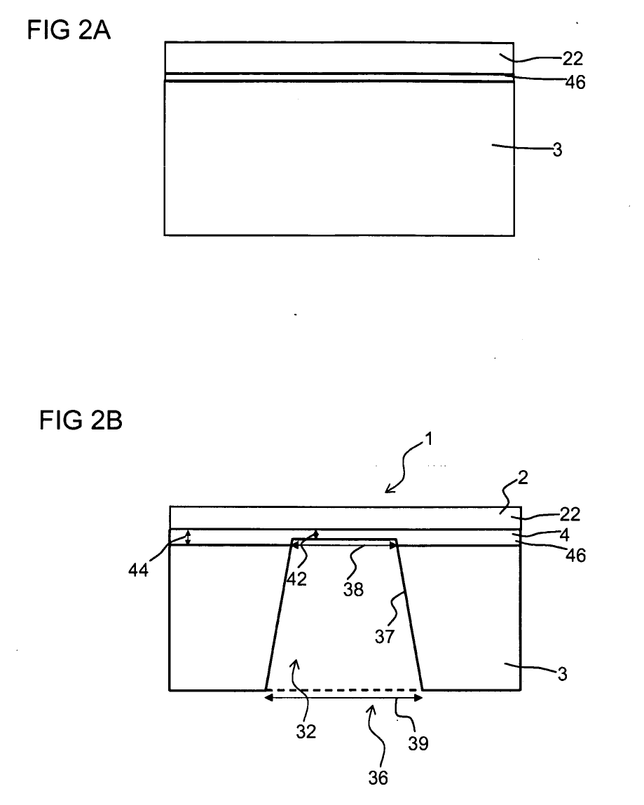

FIGS. 2A and 2B show a first process for producing a pressure sensor according to a further embodiment,

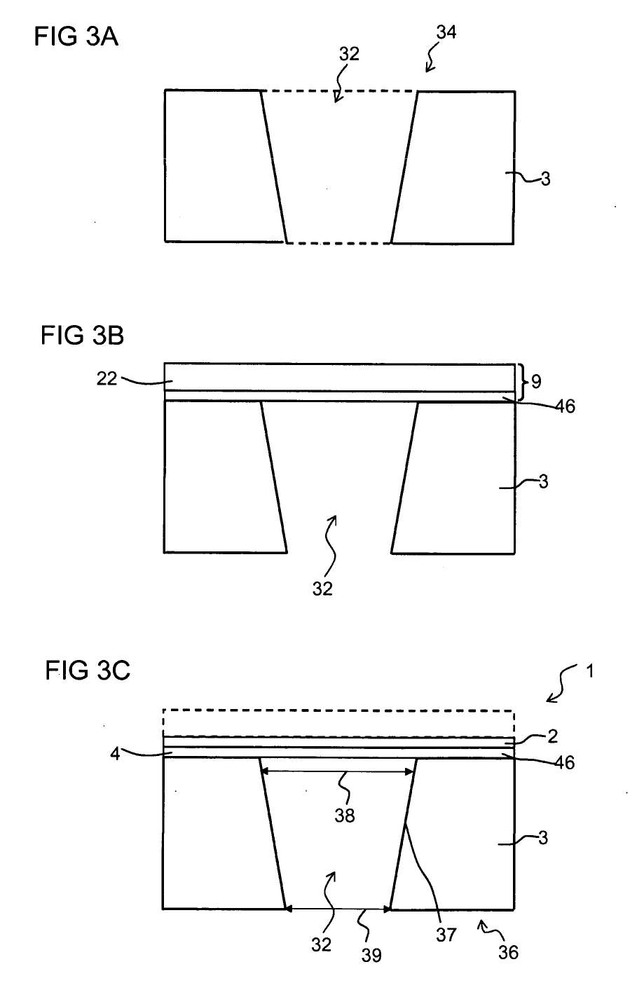

FIGS. 3A to 3C show a second process for producing a pressure sensor according to a further embodiment,

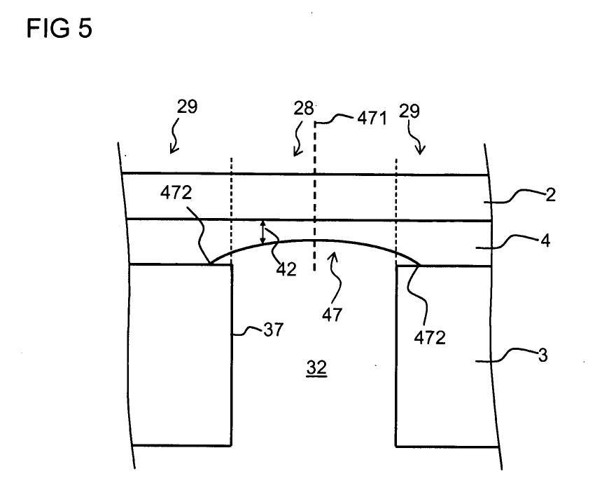

FIG. 4 shows a cross section of a further embodiment of a pressure sensor and

FIG. 5 shows a cross section of a further embodiment of a pressure sensor.

FIG. 1 shows a pressure sensor 1 which is produced using MEMS technology. The pressure sensor 1 has a piezoresistive membrane 2 which is applied to a carrier substrate 3. The membrane 2 extends over an opening 32 in the carrier substrate 3 and completely covers it. The opening 32 is a hole that passes through the carrier substrate 3. Into and through the opening 32 a medium can flow from a rear side 36 of the carrier substrate 3 and can exert a pressure on the membrane 2. The membrane 2 can be deformed by the pressure of the medium and has piezoresistive resistors which change their electrical resistance in the event of mechanical stresses.

To detect the change in resistance, electrical contacts 5 are provided which are arranged to the sides of the opening 32 on the membrane 2. The electrical contacts 5 are, for example, electrically connected to bonding wires which lead to conductor strips on a printed circuit board (not shown).

A protective layer 4 which prevents direct contact of the medium with the membrane 2 is applied to the rear side 26 of the membrane 2 which is facing the substrate 3 and the opening 32. The protective layer 4 is arranged underneath the membrane 2, in a first region 28 above the opening 32, and completely covers the membrane 2 above the opening 32. The first region 28 is situated inside an area 27 of the cross sectional area 38 of the opening 32, projected onto that side of the carrier substrate 3 facing the membrane 2. Moreover, the protective layer 4 also extends into a second region 29 outside the opening 32 and is arranged there between the carrier substrate 3 and the membrane 2. The protective layer 4 completely covers the membrane 2 outside the opening 32 too. In this way, a particularly reliable insulation of the membrane 2 can be achieved. In particular, the membrane 2 is also not accessible at the inner edges 33 of the opening 32 for the medium.

The membrane 2 and the carrier substrate 3 are formed from doped silicon. To configure the desired piezoresistive properties, the piezoresistive resistors of the membrane are produced by an additional doping, for example with boron or arsenic. The protective layer 4 comprises at least one of the materials silicon dioxide and silicon nitride or consists of these materials.

The thickness of the membrane 2 is, for example, 10 μm and the thickness of the protective layer 4 is, for example, 1 μm.

FIGS. 2A and 2B show a process for producing a pressure sensor 1 of this type. As shown in FIG. 2A, a carrier substrate 3 is provided here on which a first layer 46 for forming a protective layer 4 is arranged. A second layer 22 from which the membrane 2 is formed is situated on this first layer 46.

As shown in FIG. 2B, beginning from an underside 36 of the carrier substrate 3 facing away from layers 46 and 22, a part of the carrier substrate 3 is removed in an etching process so that an opening 32 is formed which is arranged underneath the second layer 22 and is bounded by the first layer 46 from above. In other words, the opening 32 is covered and delimited by the first layer 46. In this way, a membrane 2 is created from the second layer 22 which can, in a later operation of the pressure sensor 1, be deformed by the action of the pressure of a medium.

The material of the first layer 46 is selected such that it forms an etch stop during the etching of the opening 32. For example, the etching operation takes place at a considerably slower rate in the first layer 46 than in the carrier substrate 3. In this way, the etching process can be controlled in a simple manner such that the first layer 46 remains in its entirety above the opening 32, or a partial layer of the first layer 46 remains. For example, the thickness 42 of the thus formed protective layer 46 inside the opening 32 can be smaller than the thickness 44 of the protective layer 46 outside the opening 32. In this way, the deformation properties of the membrane 2 can be specifically configured. The relatively low speed at which the first layer 46 is etched makes it possible to configure the remaining layer thickness exactly.

As can be seen in FIG. 2B, the opening 32 has inclined inner walls 37 which are created in the etching process. As the opening 32 is etched from the underside of the carrier substrate 3, the cross sectional area 38 of the opening 32 on that side of the carrier substrate 3 facing the membrane 2 is smaller than the cross sectional area 39 of the opening 32 on that side of the carrier substrate 3 facing away from the membrane 2.

FIGS. 3A to 3C show a process for producing a pressure sensor according to a further embodiment.

As shown in FIG. 3A, a carrier substrate 3 is provided in the form of a silicon wafer. In an etching process, an opening 32 is formed which passes through the carrier substrate 3. The etching process thereby begins from a top side 34 of the carrier substrate 3.

As shown in FIG. 3B, a functional substrate 9 is then provided and connected to the top side 34 of the carrier substrate 3. The functional substrate 9 has on an outer side a first layer 46 for forming a protective layer 4. The first layer 46 adjoins a second layer 22 from which the membrane 2 is formed.

The functional substrate 9 is arranged on the carrier substrate 3 in such a way that the first layer 46 adjoins the carrier substrate 3. The functional substrate 9 is connected to the carrier substrate 3, for example by means of fusion bonding or another wafer bonding process.

As shown in FIG. 3C, a partial layer of the second layer 22 is then removed from the top side of the functional substrate 9 so that only a thin membrane 2 remains.

In this process, the opening 32 is etched from the top side 34 of the carrier substrate 3. In this case, the cross sectional area 38 of the opening 32 on that side of the carrier substrate 3 facing the membrane 2 is larger than the cross sectional area 39 of the opening 32 on that side of the carrier substrate 3 facing away from the membrane 2. The maximum cross sectional area of the opening 32 is thus situated directly underneath the membrane 2 and the protective layer 4 and so contributes to the deformability of the membrane 2. In comparison with a process in which the opening 32 is introduced from an underside 36 of the carrier substrate 3, this allows a particularly good use of the wafer area.

FIG. 4 shows a further exemplary embodiment for a pressure sensor 1. The carrier substrate 3 is applied to a further carrier body 7. The carrier body 7 is, for example, a structured glass body and serves to mechanically stabilize the pressure sensor 1.

A further layer 6 is applied to the front side 25 of the membrane 2. The material of the further layer 6 comprises, for example, silicon, silicon dioxide or silicon nitride. The further layer 6 is, for example, approximately 100 mm thick and is formed by evaporation deposition or oxidation. This further layer 6 provides protection of the membrane from a top side 14 of the pressure sensor too.

A housing 8 is applied above that part of the membrane 2 which is arranged directly above the opening 32. The housing 8 has a hollow space 82 which adjoins the membrane 2. A vacuum is formed in the hollow space 82. In this way, an absolute pressure can be measured by means of the pressure sensor 1. Moreover, the housing 8 protects at least the pressure-sensitive part of the membrane 2 from external influences.

In FIG. 5, a further embodiment of a pressure sensor is partially shown, which comprises a protective layer 4 having an indentation 47 facing the opening 32.

The indentation 47 is formed as a concave recess in the protective layer 4, having a depth which decreases in a direction from a center 471 of the indentation toward the inner wall 37 of the opening and toward the border 472 of the indentation 47. The center 471 of the indentation 47 is schematically depicted by the dashed line and preferably corresponds to the center of the opening 32.

The embodiment shown in FIG. 5, the indentation 47 has a round, concave profile so that, advantageously, the flexural stress in the membrane 2, which occurs due to the pressure of a medium deforming the membrane 2, can be equally distributed.

Accordingly, the thickness 42 of the protective layer 4 is smallest at the center 471 of the indentation 47 and increases in a direction from the center 471 toward the inner wall 37 of the opening 32 and toward the border 472 of the indentation 47. At the border 472 of the indentation 47, the protective layer 4 has an interface with the carrier substrate 3.

The position of the inner wall 37 of the opening 32 corresponds to the border between the first and the second regions 28, 29 as depicted by the dashed lines. As can be seen in FIG. 5, the indentation 47 completely covers the first region 28 and extends partially into the second region 29 so that the indentation 47 completely lies in the first region 28 and in a part of the second region 29, wherein the border 472 of the indentation 47 lies in the second region 29.

The opening 32 in the carrier substrate 3 and the indentation 47 in the protective layer 4 form an undercut wherein the surface area of the indentation 47 in a plane of the interface between the protective layer 4 and the carrier substrate 3 is larger than the surface area of the opening 32.

Moreover, the pressure sensor according to the embodiment of FIG. 5 can comprise further features as described in connection with FIGS. 1 to 4. In particular, the indentation 47 can be formed for example by selectively etching the protective layer 4 through the opening in combination with any of the before-mentioned process steps and embodiments.

### LIST OF REFERENCE NUMERALS

1 pressure sensor
14 top side
16 underside
2 membrane
22 second layer
25 top side of the membrane
26 underside of the membrane
27 projected area
28 first region inside the opening
29 second region inside the opening
3 carrier substrate
32 opening
33 inner edge
34 top side of the carrier substrate
36 underside of the carrier substrate
37 inner wall of the opening
38 cross sectional area of the opening on that side of the carrier substrate facing the membrane
39 cross sectional area of the opening on that side of the carrier substrate facing away from the membrane
4 protective layer
42 thickness of the protective layer inside the opening
44 thickness of the protective layer outside the opening
46 first layer
47 indentation
471 center
472 border
5 electrical contact
6 further layer
7 carrier body
8 housing
82 hollow space
9 functional substrate

1. A pressure sensor, comprising:
a piezoresistive membrane which can be deformed by the action of the pressure of a medium,
a carrier substrate on which the membrane is arranged, the carrier substrate having an opening over at least part of which the membrane extends,
and a protective layer to protect the membrane from direct contact with the medium,
the protective layer covering the membrane both in a first region inside the opening and in a second region outside the opening.

2. The pressure sensor according to claim 1,
in which the protective layer completely covers the membrane inside the opening.

3. The pressure sensor according to claim 1,
in which the second region adjoins the first region directly.

4. The pressure sensor according to claim 1,
in which the protective layer completely covers the membrane outside the opening.

5. The pressure sensor according to claim 1,
in which the carrier substrate has a top side and an underside,
in which the protective layer is situated on the top side of the carrier substrate and is fixedly connected to it, and
in which the membrane is arranged on a side of the protective layer facing away from the carrier substrate.

6. The pressure sensor according to claim 1,
in which the material of the carrier substrate can be etched selectively against the material of the protective layer.

7. The pressure sensor according to claim 1,
in which the protective layer comprises at least one of the materials silicon dioxide and silicon nitride.

8. The pressure sensor according to claim 1,
in which the thickness of the protective layer in the first region inside the opening is smaller than the thickness of the protective layer in the second region outside the opening.

9. The pressure sensor according to claim 1,
in which the protective layer has an indentation facing the opening, wherein the protective layer has a thickness which increases from a center of the indentation toward a border of the indentation and wherein the indentation completely covers the first region and extends into the second region.

10. The pressure sensor according to claim 1,
with at least one further layer which is arranged on a side of the membrane facing away from the protective layer.

11. The pressure sensor according to claim 1,
with a housing which is arranged on a side of the membrane facing away from the carrier substrate and has a hollow space that adjoins the membrane.

12. A process for producing a pressure sensor, comprising the steps:
A) Providing a carrier substrate on which a first layer is arranged for forming a protective layer to protect a membrane from direct contact with a medium, and above this a second layer is arranged for forming a membrane,
B) Forming an opening in the carrier substrate so that at least a part of the layer thickness of the first layer and the second layer remains completely above the opening.

13. The process according to claim 12,
in which in step B) the opening is formed in the carrier substrate in a structuring etching process and the protective layer thus forms an etch stop.

14. A process for producing a pressure sensor, comprising the steps:
A) Providing a carrier substrate,
B) Forming an opening passing through the carrier substrate,
C) Providing a functional substrate which on an outer side has a first layer for forming a protective layer to protect a membrane from direct contact with a medium, and arranged thereunder a second layer for forming a membrane,
D) Applying the functional substrate with the first layer to the carrier substrate so that at least a part of the first layer is arranged above the opening in the carrier substrate,
E) Removing a part of the second layer of the functional substrate and thus forming a membrane from the second layer.

15. The process according to claim 14,
in which an indentation is formed in the protective layer, wherein the indentation faces the opening, wherein the protective layer has a thickness which increases from a center of the indentation toward a border of the indentation and wherein the indentation completely covers the first region and extends into the second region.
